(19) United States
(12) Patent Application Publication
(10) Pub. No.: US 2011/0124135 A1
(43) Pub. Date: May 26, 2011

(54) Solar Cell Module and Method for Assembling a Solar Cell Module

(75) Inventors: Lawrence A. Clevenger, Hopewell Junction, NY (US); Kevin S. Petrarca, Newburgh, NY (US); Rainer Klaus Krause, Kostheim (DE); Brian C. Sapp, Hopewell Junction, NY (US)

(73) Assignee: International Business Machines Corporation, Armonk, NY (US)

(21) Appl. No.: 12/947,227

(22) Filed: Nov. 16, 2010

(30) Foreign Application Priority Data
Nov. 24, 2009 (DE) 09176822.6

(51) Int. Cl. H01L 21/66

(52) U.S. Cl. 438/15; 257/E21.531

(57) ABSTRACT

The invention relates to a method for assembly of solar cell modules by arranging a multitude pre-manufactured, individualized solar cells for forming a matrix of solar cells for the solar cell module; depositing a metallization layer at least partially on at least one surface of the matrix of solar cells for forming the solar cell module; testing electrical function at least of the solar cell module; depositing a passivation layer on a surface of the solar cell module. In another aspect the invention relates to a manufacturing system for a solar cell module and a solar cell module (26) comprising a matrix of pre-manufactured and individualized solar cells and manufactured according to the aforementioned method.

### FIELD OF THE INVENTION

The present invention relates to a method and a manufacturing system for assembling a solar cell module.

### BACKGROUND OF THE INVENTION

Solar cell modules are typically assembled using an end-to-end process, wherein a solar cell module comprising a multitude of pre-manufactured, individualized solar cells is automatically manufactured in a line production. Thereby, solar cell modules are assembled by arranging pre-manufactured, individualized solar cells having a metallization on the back surface thereof and a stripe and finger metallization grid on the front surface of each solar cell, and whereby each solar cell is passivated and encapsulated individually.

In conventional solar cell manufacturing lines, said pre-manufactured solar cells are arranged in a matrix form and are electrically connected in series to form a solar cell module. As such, the step of manufacturing a solar cell module includes nothing more than arranging pre-manufactured, pre-metallized and pre-passivated solar cells in a solar cell matrix and wiring the solar cells for forming an electrical series connection of solar cells of the solar cell module.

A method for manufacturing solar cell modules based on a fabrication of solar cells on module level is proposed, whereby a multitude of solar cells are formed within a substrate having the dimensions of a solar cell module. Thus, solar cell manufacturing on module level leads to a solar cell module with solar cells integrally formed so that a malfunction of a single solar cell leads to a malfunction of the whole solar cell module.

Another solar cell manufacturing method on module level is disclosed in U.S. Pat. No. 4,879,251 A. According to the revealed method, an electrically conductive layer is applied onto a surface of a large area substrate covering the entire solar cell module, a p-doped silicon layer is applied onto the surface of said conductive layer and a p-n-junction is formed by introducing n-doped atoms, whereby trenches are subsequently formed for electrically separating individual solar cells of the solar cell module and these trenches are filled with insulating material and holes are formed for providing an in-series connection between the individual cells. Finally, a metallic grid structure is formed on the front surface of the individual cells of the solar cell module. Thereby, a solar cell module having integrally formed solar cells is proposed, whereby malfunction of a single solar cell leads to malfunction of the whole solar cell module.

U.S. Pat. No. 6,420,643 B2 proposes a solar cell and a solar cell module, wherein pre-manufactured solar cells comprising a first ohmic contact layer, a first and a second layer of doped semiconductor material and a second ohmic contact layer are disposed on an electrically insulating substrate, and an electrically conductive connection providing electrical communication between said second ohmic contact layer of one solar cell and said first ohmic contact layer of the other solar cell is established to form the solar cell module. Thus, a solar cell module comprising individualized solar cells having back and front metallization layers is provided.

In conclusion, it is well known to assemble solar cell modules by combining pre-manufactured complete solar cells or by integrally forming solar cells on a module level. Thereby, each of both methods has advantages, whereby the possibility to manufacture photovoltaic solar cells at the module level yields many benefits. Lead time significantly improves the manufacturing of several cells at one time at module level and offers the advantage of tighter manufacturing abilities and equal solar cell quality in one module, which leads to better cell matching at module level. Furthermore, module level cell manufacturing offers reduced firing temperature and metallization time, whereby passivation can be applied after metallization. A drawback of the aforementioned solar cell manufacturing on module level can be seen in the integral combination of the solar cells within the module, which does not allow for individual testing and replacing of defective or underperforming solar cells within the module.

Therefore, a manufacturing method, a manufacturing system and a solar cell module are required, combining advantages of both methods of manufacturing solar cells on module level and combining pre-manufactured solar cells for forming a solar cell module, thereby omitting the aforementioned disadvantages of each method.

### SUMMARY OF THE INVENTION

It is an object of the present invention to provide an assembling method, a solar cell module and a manufacturing system, whereby individual solar cells are at least partially pre-manufactured, can be individually tested at module level and final steps of solar cell module manufacturing, such as metallization of at least the front surface as well as passivation, can be performed at module level. Thereby replacing weak or defective solar cells can be performed at module level during the manufacturing process.

A method for assembling a solar cell module is proposed, comprising the steps of:
arranging a multitude of pre-manufactured, individualized solar cells for forming a matrix of solar cells for the solar cell module;
depositing a metallization layer at least partially on at least one surface of the matrix of solar cells for forming the solar cell module;
testing electrical functioning at least of the solar cell module;
depositing a passivation layer on a surface of the solar cell module.

According to the present invention, a solar cell module is assembled by arranging pre-manufactured, individualized solar cells in a solar cell matrix, preferably by a pick and place method, so that a matrix aligned group of solar cells forms the basis of the solar cell module. A metallization layer is applied at module level onto at least one surface of the matrix, preferably onto the front surface of each solar cell, whereby each individual solar cell can have a back surface which is electrically conductive. The step of depositing a metallization layer is followed by a step of testing of electrical functioning of at least the whole solar cell module, whereby individual solar cells or a group of solar cells can also be tested, and in case of malfunctioning or underperforming the affected solar cells can easily be replaced by other error-free solar cells. Finally, a passivation layer, preferably an anti-reflection layer, is deposited on the front surface of the solar cells for passivation and protection of the solar cell module.

As such, some steps of manufacturing solar cell modules are performed on solar cell level, for example providing a p-n-doped substrate, metallizing a back surface of a solar cell, and some steps are performed on module level, such as applying a metallization, preferably on the front surface, for providing a metallic contact pattern, enabling testing of the whole solar cell module and also of individual or groups of solar cells, and finally depositing a passivation layer on at least one surface of the solar cell module as a final step on module level. In this way, production costs are lowered and production efficiency is enhanced. Furthermore, certain production steps, such as firing temperature for applying the metallization layer, and production times are reduced. As a result, a repairable solar cell module with improved quality and reduced production time is provided.

The inventive method offers the advantage that the cells are exposed to metallization and passivation at module level. Therefore, the final steps of assembling the cells on module level are accomplished simultaneously for all cells within the module. This aspect allows for a significant improvement potential concerning lead time as well as cell matching and guarantees a constant quality of solar cell module manufacturing. Certain steps of common production methods can be adapted to the proposed inventive method, such as pre-manufacturing of solar cells on cell level. Therefore, the inventive method combines 50% of cell manufacturing with 50% of module level manufacturing. The solar cell module assembling process requires new tooling which should be pretty much available at this form factor, see for instance thin-film technology. The inventive method changes a paradigm in connection with the currently used end-to-end photovoltaic manufacturing process. The aforementioned advancements do not only enable reduced costs but also improve yield due to reduced scrap rate. Therefore, the inventive method offers improved cell matching within a module and rework feasibility at least during manufacturing time. By way of example, losses through handling, like wafer breakage, at module level have less cost impact compared to finished cell breakage.

According to a favorable embodiment of the present invention, a step of providing a multitude of pre-manufactured, individualized solar cells sorted into one or more groups according to one or more parameters of the solar cell can be performed. In this way, pre-manufactured, individualized solar cells can be used for the pick and place arrangement method of solar cells to form a solar cell matrix, whereby each solar cell comprises a photoactive p-n-junction and is sorted into bins having comparable properties, such as electrical efficiency, equal production quality, same wafer and doping material etc. to provide nearly identical quality of solar cells combined in the solar cell module. As a result, the solar cell modules have a distinct quality, efficiency and service life, whereby high volumes of predetermined quality levels of solar cell modules can be manufactured in a line production method.

According to another favorable embodiment of the inventive method, the pre-manufactured, individualized solar cells can be arranged using a position alignment method, preferably a laser alignment method or a mask alignment method. A high precision alignment of the individual solar cells in the solar cell matrix for forming a solar cell module is imperative if following assembly steps are based on an exact alignment. The step of depositing a metallization layer on module level is such a step, wherein all or at least several pre-arranged groups of solar cells are metallized at the same time. Therefore, a high precision computer controlled alignment, which can be achieved by a laser alignment method or similar methods, is highly advantageous in order to guarantee high quality of the solar cell module.

In general, the individualized solar cells, which are arranged in a solar cell matrix, can be selected arbitrarily from any solar cells resulting from an ordinary solar cell manufacturing process. In a favorable embodiment, an electrical pre-testing step before arranging the pre-manufactured, individualized solar cells in the matrix of at least some of the pre-manufactured, individualized solar cells can be performed. Such a pre-testing step can be implemented, particularly by temporarily electrically contacting and testing of at least some solar cells before arranging the cells in a matrix of a solar cell module. Pre-testing of the solar cells significantly reduces time and effort spent for replacing solar cells on module level, thus reduces production costs and increases quality of the solar cell module.

According to a favorable embodiment, a selective doping process of a pattern into the substrate of at least some of the solar cells can be performed, preferably a laser ablation doping process, before covering the at least one surface at least partially with a metallization layer, particularly for providing a dual emitter doping pattern. Such a structured doping pattern can be formed by area-selective doping of the front surface of the solar cells, such that areas covered by metallic contact patterns, such as metallic fingers or stripes of a front surface contacting pattern, cover areas of highly doped substrates, thus reducing contact resistance between metallization and substrate. A highly precise alignment of individualized solar cells having a pre-doped dual emitter pattern on a substrate surface is highly complicated, whereby a metallization on module level matching the doped pattern of the aligned solar cells can not always be deposited with sufficient accuracy. Thus a step of selective doping of a pattern, especially a dual emitter pattern on module level, can ensure an exact alignment of the patterns of all solar cells arranged in the solar cell matrix. Thus, the following step of metallization—also on module level—can provide a perfectly aligned doping pattern for providing a dual emitter structure. In this way, a solar cell module comprising a structured doped pattern as a dual emitter pattern offers reduced contact resistance and higher power efficiency.

According to another favorable embodiment, depositing the metallization layer on the at least one surface of the solar cell matrix for providing a metallic contact pattern, preferably on the front surface of the solar cell matrix, is performed using one of the following methods: screen-printing, stamping or plating. Such methods for depositing a metallization layer through a lithography-type process are well known from state of the art, whereby such reliable and effective depositing methods at the cell level can easily be transferred to a manufacturing process at module level.

After arranging the solar cells in a matrix of a solar cell module and depositing a metallization layer on a front surface and/or back surface of the cells, an electrical wiring of adjacent solar cells can be applied to provide a series connection of at least some of the solar cells in the solar cell module. According to a favorable embodiment, said electrical wiring of adjacent solar cells can be applied to the metallization layer, preferably by soldering, bonding, contact clip, or other detachable contacts, supporting replaceable contacts and/or replaceable wiring. Such replaceable contact or wiring for connecting adjacent solar cells, preferably using in series connection, is useful for replacing malfunctioning or underperforming solar cells in the matrix of the solar cell module, and are therefore advantageous for testing and repairing a solar cell module during the manufacturing process.

According to the inventive method, a testing of the electrical functioning at least of the solar cell module can be performed. A favorable embodiment proposes to test at least a single solar cell or a group of solar cells of the solar cell module, especially all solar cells contained in the solar cell module. Testing can comprise an electrically functional testing with aspect to short circuit current, open circuit voltage and power output in case of a defined light exposure. Testing individual cells ensures error-free quality of the whole solar cell module, whereby a step of testing implemented in the manufacturing process of the solar cell module opens the possibility of repairing solar cells by replacing defective solar cells by error-free solar cells. Testing each solar cell guarantees a 100% error-free solar cell module enhancing the quality of the solar cells and reducing the scrap rate to nearly 0%.

In case that not only the whole solar cell module is tested, but individual or groups of solar cells are tested, individual defective solar cells can be detected. According to a favorable embodiment, such weak and/or malfunctioning solar cells can be replaced by solar cells assigned to the same group to improve solar cell module efficiency and quality before finishing the manufacturing process of the solar cell module. In other words, after depositing a metallization on one or on both surfaces of the solar cells and wiring of adjacent cells a selective testing of individual or groups of solar cells can be performed, whereby weak or malfunctioning solar cells having no electrical power output or having a reduced electrical power output can be replaced by comparable cells assigned to the same group to improve quality and efficiency of the solar cell module. In this way, nearly 100% error-free solar cell modules can be manufactured.

According to another favorable embodiment of the present invention, the deposition of the passivation layer on a surface of the solar cell module can be followed by a step of encapsulation of the solar cell module. An encapsulation, preferably by using a transparent and non-aging transparent polymer resin as encapsulation material, can be performed as a final manufacturing step encapsulating the whole solar cell module to ensure protection of the solar cells against environmental impacts, like rain or wind effects and can protect the solar cells from damage during the installation process. After encapsulation of the solar cell module, testing and replacing of individual cells is rendered much more complicated, but can still be performed.

Another aspect of the invention can be seen in that a solar cell module is provided, comprising a matrix of pre-manufactured and individualized solar cells manufactured according to any of the aforementioned methods. Thereby, a solar cell module resulting from such a method can be manufactured nearly 100% error-free due to testing and replacing of defective solar cells during the manufacturing process. Assembly costs and effort spent in connection with such solar cell modules, combining manufacturing steps on cell level and manufacturing steps on module level, are reduced in comparison to manufacturing methods known from the state of the art. Therefore, technical quality is enhanced and production costs for such solar cells are decreased.

According to a favorable embodiment of the solar cell module, at least some of the pre-manufactured, individualized solar cells in the matrix comprise a pattern doped substrate, particularly a dual emitter doped substrate. Such a pattern doped substrate, particularly a dual emitter doped substrate, can be implemented in the substrate of the solar cell on solar cell level, but according to a favorable embodiment of the inventive method also on module level. Particularly a dual emitter doped substrate enhances the electrical properties of the solar cells and improves efficiency of the solar cell module.

Another favorable embodiment of the solar cell can be realized by using pre-manufactured, individualized solar cells in the solar cell matrix, which comprise a metallized back surface. The pre-manufactured, individualized solar cells can be manufactured by depositing a metallized back surface, so that arranging the solar cells in a solar cell matrix provides a matrix of solar cells, wherein additional manufacturing steps on module level must solely be performed on the front surface of the solar cell, since the back surface of each cell is fully metallized and ready for wiring without the need for performing another manufacturing step. Therefore, pre-metallized back surfaces of individualized solar cells decrease manufacturing costs and time.

After depositing a metallization layer on the solar cells, a wiring of the solar cells, preferably by implementing an in series connection of the solar cells of the module, have to be performed. In a favorable embodiment of the solar cell module, detachable contacts and/or wiring can be provided for replacing weak and/or malfunctioning solar cells. Use of detachable contacts of the metallization grid on the front surface of the solar cell and use of detachable wiring between adjacent cells for providing in series connection enables individual testing and replacing of weak or malfunctioning solar cells. As such, the testing and replacing step performed during the manufacturing process of solar cell modules can be facilitated easily, thus saving time and costs.

According to another aspect of the present invention, a manufacturing system for manufacturing a solar cell module is proposed, which is based on a method according to anyone of claims 1 to 10. Preferably, the manufacturing system is implemented as a fully automated production line, wherein each method step is reflected by an autonomously working production unit providing an end-to-end manufacturing facility.

### BRIEF DESCRIPTION OF THE DRAWINGS

The present invention together with the above-mentioned and other objects and advantages may best be understood from the following detailed description of the embodiments, but is not restricted to the embodiments, as shown in:

FIG. 1 a workflow according to a first embodiment of the inventive method;

FIG. 2 a schematic specification of production steps according to the first embodiment of the inventive method;

FIG. 3 a workflow according to a second embodiment of the inventive method;

FIG. 4 a schematic specification of production steps according to the second embodiment of the inventive method; and

FIG. 5 a schematic representation of a laser doping device for providing a selectively doped pattern onto a front surface of a matrix of solar cells on module level.

In the drawings, like elements are referred to with equal reference numerals. The drawings are merely schematic representations, not intended to portray specific parameters of the invention. Moreover, the drawings are intended to depict only typical embodiments of the invention and therefore should not be considered as limiting the scope of the invention.

### DETAILED DESCRIPTION OF EXAMPLE EMBODIMENTS

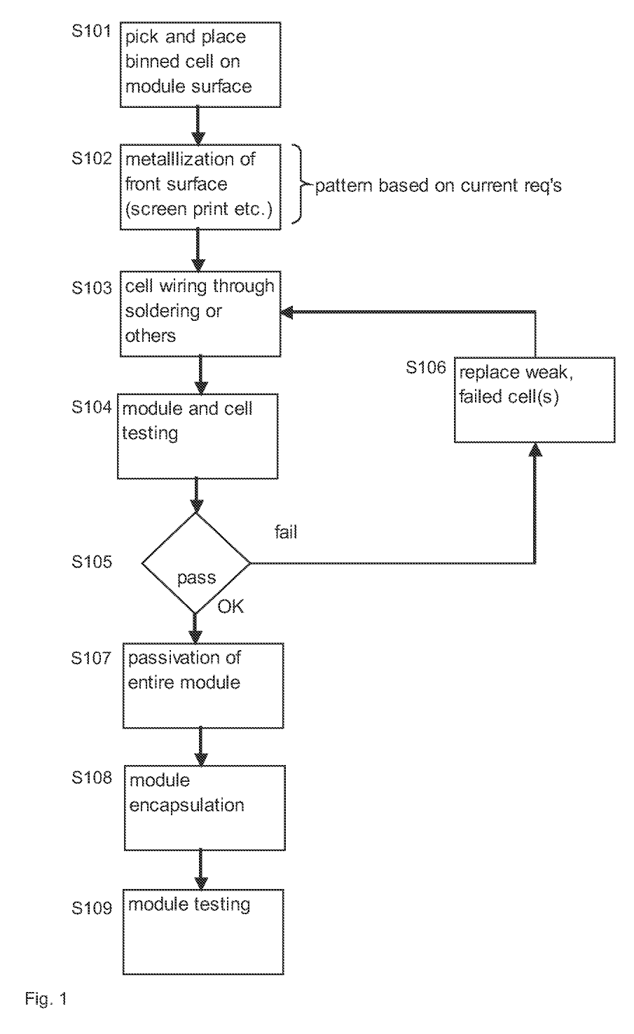

FIG. 1 shows a workflow according to a first embodiment of the method for assembling solar cells at module level. This first embodiment represents a manufacturing method for standard photovoltaic solar cells. In a first step S101, a multitude of pre-manufactured, individualized and sorted solar cells, which can be referred to as binned cells, are arranged by a pick-and-place process on a module surface to form a solar cell matrix. The solar cells may be sorted with respect to equal quality and comparable electrical specification. During the following step S102, a metallization of the front surfaces of all solar cells arranged in the matrix is performed, e.g. by screen-printing, stamping or other comparable lithographic processes to form a metallic contact pattern comprising metallic fingers and stripes on the front surface of all solar cells, whereby form and thickness of the metallic pattern are based on current requirements oriented to the power performance of the solar cell module.

During step S103, a cell wiring through soldering or other comparable electrically contacting method is performed for electrically connecting adjacent solar cells in series, whereby preferably replaceable wiring and replaceable contacts are used, so that wiring and contacts of individual solar cells of the solar cell matrix can be uninstalled and individual solar cells can be replaced by other solar cells.

In step S104, the whole module, individual cells or groups of cells are electrically tested ensuring that power performance, current requirements and other technical properties are met by the solar cells and the module.

If the tested solar cells, groups of solar cells and the whole module pass the test in step S105 (“OK” in the flow chart), a completion of solar cell module manufacturing is followed in the next steps.

If the module and solar cell testing fails (“fail” in the flow chart), the detected weak or malfunctioning solar cells are replaced by error-free solar cells in step S106, comprising a cell de-wiring and dissolving of the affected solar cell and a replacement of the affected cell by a new cell is followed by a rewiring of the new solar cell in step S103.

Having tested at least the module in step S107, a passivation of the entire module is performed by coating the front surface of all solar cells comprised by the solar cell module with an anti-reflective and protective layer, and in step S108 a module encapsulation by using a transparent resin offering protection against environmental impacts is followed.

Finally, the whole module is tested in step S109 before delivering the solar cell module to an end customer where it can be installed on a roof of a house or in a photovoltaic power plant.

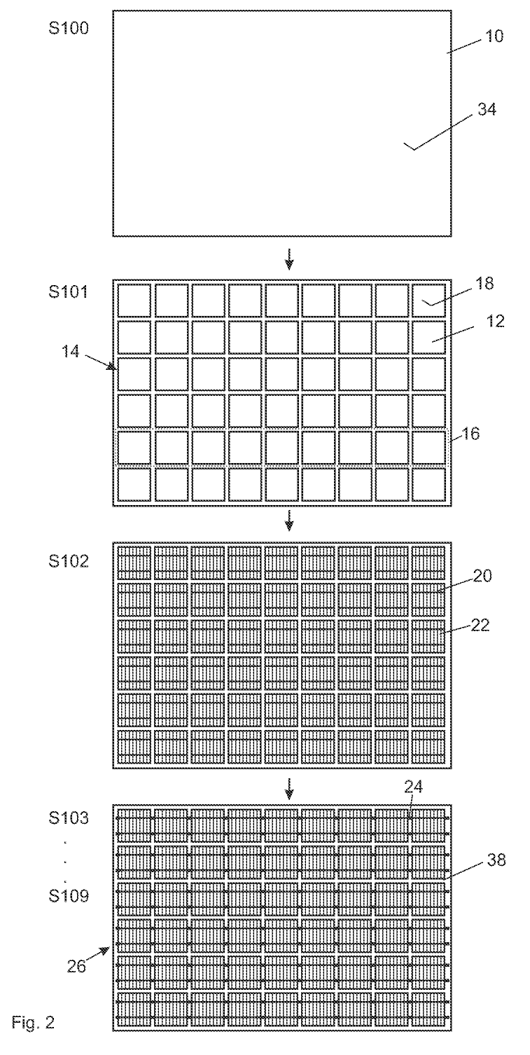

FIG. 2 schematically shows some assembly steps of a solar cell module manufactured according to the first embodiment of the assembly method. In step S100, a module matrix frame 10 is displayed which comprises an insulation layer 34 covering the back side of the matrix frame, so that individual solar cells having a metallized back side are insulated when arranged on the insulation layer 34.

Step S101 shows an arrangement of a multitude of pre-manufactured, individualized solar cells in a solar cell matrix 14 within a solar module matrix frame 10, whereby each solar cell 12 has a metallized back surface and individual solar cells 12 are arranged in lines thus forming groups of solar cells 16.

In the following step S102, a front surface metallization layer 20 is deposited on the front surface of the solar cell matrix 14 forming the metallic contact pattern 22 comprising stripes and fingers for contacting the front surface 18 of the solar cell substrates for electrical contacting of the solar cells 12.

During the following steps S103 to S109, which had been described in FIG. 1, further processing steps on module level comprising a wiring of adjacent cells of the solar cell matrix 24 and depositing a passivation layer 38 on the front surface of the solar cell module 26 providing an anti-reflective layer are performed to finalize the manufacturing of the solar cell module 26. In the course of wiring adjacent solar cells 12, an electrical testing of individual solar cells and replacing of weak or malfunctioning solar cells is performed.

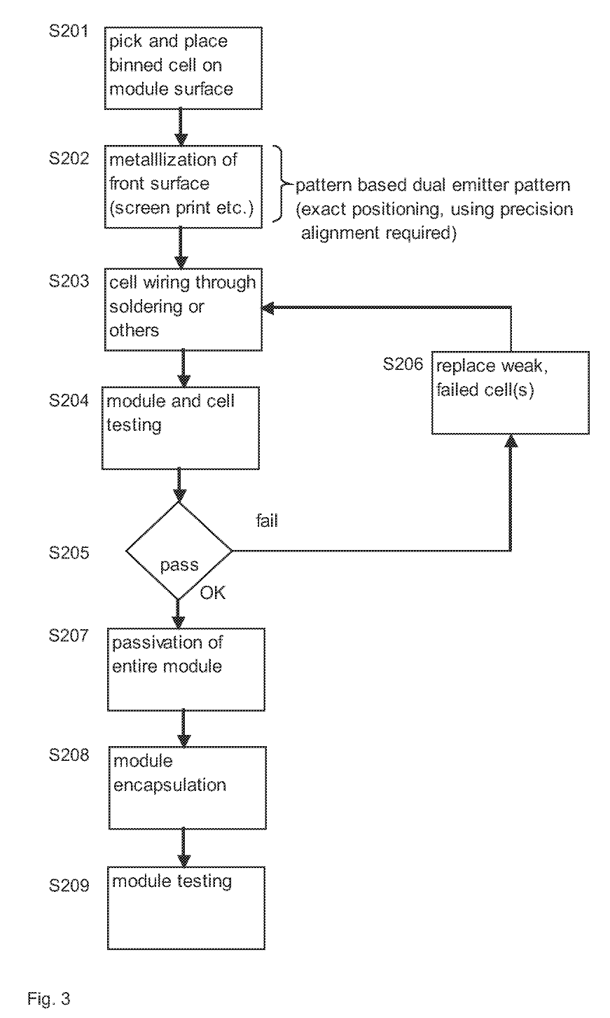

FIG. 3 shows a second embodiment of the assembly method comprising steps S201 to S209. Steps S201 and S203 to S209 are similar to steps S101 and S103 to S109 of the first embodiment. Thereby, in step S201 an arrangement of individualized solar cells is performed by a pick and place method of binned cells into a matrix frame 10 of a module. In step S202, a metallization layer 20 of the front surface by screen-printing, stamping or plating is deposited on the front surface of the solar cell matrix. Within step S202 before depositing the metallization layer 20 a dual emitter pattern is doped into the solar cell substrate for reducing the contacting resistance between the metallic contact pattern 20 and the substrate. Such pattern based doping of a multitude of matrix arranged solar cells requires an exact positioning of the dopant atoms within the solar call matrix which can be provided by a high precision doping pattern alignment method, e.g. a laser ablation doping method or mask alignment method etc.

After selective doping of at least some solar cell surfaces on module level, in subsequent step S203, a wiring of adjacent cells is performed by soldering or other electrically connecting methods, whereby in step S204, the electrical performance of the individual solar cells is tested and in step S205, in case that some solar cells fail to pass the test (“fail” in the flow chart), the weak solar cells are replaced in step S206, whereby the replaced solar cells are rewired and resoldered in step S203 and are subsequently additionally tested in step S204. In case that all solar cells in the solar cell matrix pass the test (“OK” in the flow chart), a passivation of the entire module is performed in step S207, and in step S208, the whole module is encapsulated for protecting the solar cells against environmental impacts like mechanical damage, rain and wind. Finally, in step S209, the whole solar cell module is tested and subsequently delivered to the end customer for installation in a photovoltaic power generation device.

The second embodiment differs from the first embodiment with respect to the dual emitter patterning of the solar cell substrates on module level. In case that each solar cell is manufactured comprising a dual emitter doped substrate the front surface metallization layer being deposited on module level must be placed directly on the dual emitter locations requiring a more advanced positioning system of the solar cells 12 in the solar cell matrix 14 such that the highly doped areas (dual emitter spots or lines) of all solar cells 12 are perfectly aligned.

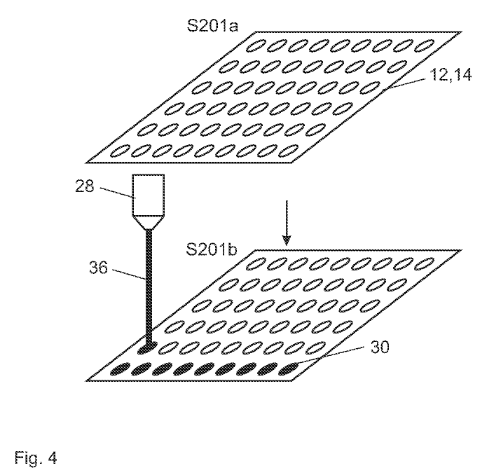

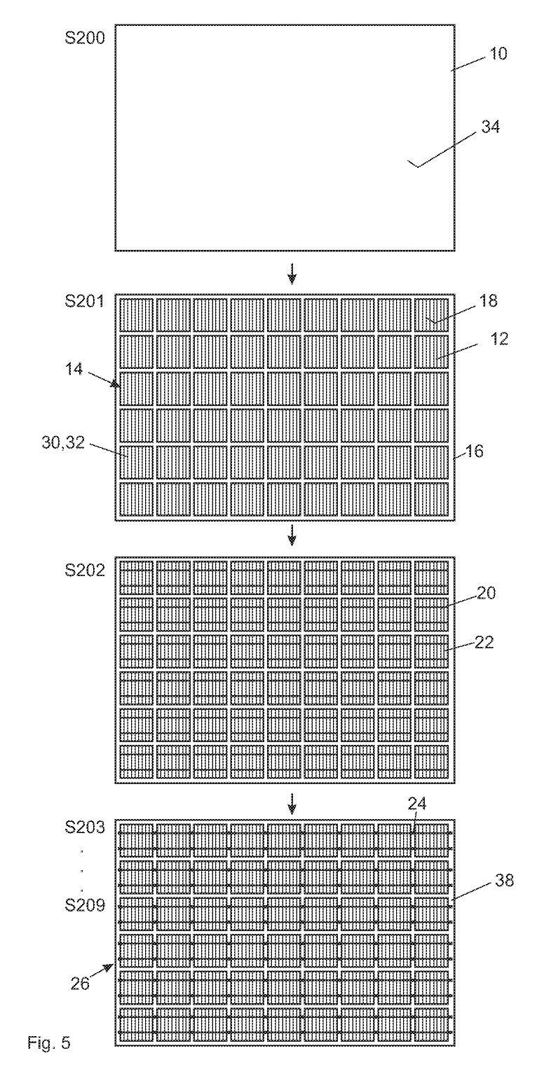

The highly doped spot or lines for a dual emitter pattern 32 can also be manufactured on module level, using laser ablation doping, see FIG. 4, wherein a computer controlled ablation laser 28 forms spots or lines on individual solar cells of a solar cell matrix 14 to form selectively doped pattern 30. Thereby, the laser beam 36 weakens the affected area of the substrate of the solar cells 12 and allows a doping material to penetrate the substrate's surface. Thus, individual solar cells 12 of a solar cell matrix 14 can be selectively doped to form a dual emitter pattern 32, see step S201 of FIG. 5 whereby the doping pattern of all solar cells 12 are perfectly aligned within the solar cell matrix 14. As such a deposition of a front surface metallization layer 20 for forming a metallic contact pattern 22 can match the dual emitter pattern 32 for reducing contacting resistance and enhancing solar module efficiency.

In FIG. 5, a schematic representation of vital steps of the method according to the second embodiment is shown. Starting from step S200, a module matrix frame 10 is provided having an insulating layer 34 covering the back of the matrix frame 10. In step S201, individual solar cells 12 having selectively doped patterns 30, in this case dual emitter patterns 32 on the front surface of each solar cell 12 are arranged using a high precision pick and place process for forming a solar cell matrix 14. Thereby, horizontal lines of adjacent solar cells 12 form a group of solar cells 16 and will be electrically connected in series in the following steps.

In the next step S202, a metallization layer 20 for forming a metallic contact pattern 22 is deposited on the front surface 18 of the matrix of solar cells 14 whereby the metallization deposition is also performed using a high precision alignment system for matching the dual emitter pattern 32 of the solar cells 12 arranged in the matrix 14.

Finally, in steps S203 to S209, a wiring of adjacent solar cells 12 within the solar cell matrix 14 is performed for electrically connecting at least a group of solar cells 16 in a series connection. After wiring the solar cells 12, an electrical testing of the group of cells 16 and also of individual solar cells 12 and the whole solar cell module 26 is performed, whereby weak or malfunctioning solar cells 12 are replaced by error-free solar cells. Subsequently, the whole solar cell module 26 is passivated using an anti-reflective passivation layer 38 covering the front surface 18 of each solar cell 12, and an encapsulation of the whole solar cell module is finally performed. Before shipping of the solar cell module 26 a final test of the electrical function of the whole solar module 26 ensures a 100% error-free quality of the solar cell 26.

The inventive manufacturing method uses advanced wafers of solar cells for module assembly and has certainly lead time improvement potential. This due to the fact, that cells are manufactured in module size batches instead of cell by cell. The calculation below is based on a 50 MWp cell manufacturing and 25 MWp module manufacturing lines.

In a state of the art sequential module manufacturing method wherein 60 individually manufactured solar cells having front and back metallization and passivation are integrated in one module. Manufacturing time of the 60 cells is 119.5 sec and of the module is 225 sec, which results in 344.5 sec in total. According to an embodiment of the inventive manufacturing method total time of manufacturing a module in an integrated cell-module-manufacturing process is 240 sec which results in a production time reduction of more than 30%, which can translate to a significant annual volume increase. This of course also reduces the MWp (peak megawatt power) cost on module level.

The next benefit certainly is the improved cell matching using the advanced module assembly process. Metallization takes place before passivation. This enables a lower firing temperature because the contact to the silicon surface improves. Also testing after metallization and cell wiring is an additional matching control with rework capability. Deposition of a passivation layer after metallization protects the surface of the module and contacts additionally. Processing of all wafers/cells in single process steps again does not improve cell matching. The delta between cell and module performance is actually fairly high with 1.5% absolute efficiency.

Typically, the efficiency factor of a bin of solar cells varies around 0.5%. Furthermore the cell to module efficiency differs around 1.5%, which trebles the problem. Due to the inventive method a better metallization, firing and testing on module level can be provided across all cells on the module, which can lead to a cell matching improvement of 0.5%. Furthermore a homogenous passivation and additional protection of the module can achieve 0.25% of matching improvement, which sums up to a total module improvement potential of 0.75%.

Assuming an actual performance of an 1.46 m² area-sized module (60 cells of 0.156 mm×0.156 m) and a 220 W maximum power for a 1 m² (one square meter) module, an overall efficiency of 15.07% (220 W/1.46=150.7 W per 1 m²) can be improved to 15.82% (15.07+0.75), whereby the peak power output of 220 Wp per module can be increased by 11 Wp (0.75·1.46·10 Wp) to 231 Wp per module. Thus the total increase of number of modules of a line production of 25 MWp modules manufactured according to the proposed method could increase from 113663 solar modules per year to 118260 solar cell modules per year (+4%), whereby additional 1.30 MWp (118260·11 Wp) of electric peak power can be provided annually through improved cell matching. The cell matching example shown above shows quite some potential with at least 5% gain in power output.

1. A method for assembling a solar cell module comprising:
arranging a plurality of pre-manufactured, individualized solar cells for forming a matrix of solar cells for the solar cell module;
depositing a metallization layer at least partially on at least one surface of the matrix of solar cells for forming the solar cell module;
testing electrical function of at least the solar cell module;
depositing a passivation layer on a surface of the solar cell module.

2. The method according to claim 1, further comprising providing the plurality of pre-manufactured, individualized solar cells sorted in one or more groups according to one or more parameters of the solar cell.

3. The method according to claim 2, further comprising arranging the pre-manufactured, individualized solar cells using a precision alignment method, preferably one of laser alignment method mask alignment.

4. The method according to claim 3, further comprising an electrical pre-testing step before arranging the pre-manufactured, individualized solar cells in the matrix of at least some of the pre-manufactured, individualized solar cells, particularly by temporarily electrically contacting and testing.

5. The method according to claim 4, wherein a selective doping of a pattern in the substrate of at least some of the solar cells is performed, preferably a laser ablation doping, before covering the at least one surface at least partially with a metallization layer, particularly for providing a dual emitter doping pattern.

6. The method according to claim 5, wherein depositing the metallization layer on the at least one surface of the solar cell matrix for providing a metallic contact pattern, preferably on the front surface of the solar cell matrix, is performed using one of the following methods: screen printing, stamping or plating.

7. The method according to claim 6, wherein an electrical wiring of adjacent solar cells is applied to the metallization layer, preferably by soldering or bonding, contact clip, detachable contacts, supporting replaceable contacts and/or replaceable wiring.

8. The method according to claim 7, wherein testing electrical function of at least the solar cell module comprises testing of at least a single solar cell or a group of solar cells of the solar cell module.

9. The method according to claim 8, further comprising replacing weak and/or malfunctioning cells by cells assigned to the same group to improve solar cell module efficiency before applying the passivation layer.

10. The method according to claim 9, wherein depositing the passivation layer on a surface of the solar cell module is followed by a step of encapsulation of the solar cell module.
